(19) United States
(12) Patent Application Publication
(10) Pub. No.: US 2011/0084395 A1
(43) Pub. Date: Apr. 14, 2011

(54) Semiconductor package substrate and semiconductor device having the same

(75) Inventors: Hiromasa Takeda, Tokyo (JP); Satoshi Isa, Tokyo (JP); Mitsuaki Katagiri, Tokyo (JP); Ken Iwakura, Tokyo (JP); Yu Hasegawa, Tokyo (JP)

(73) Assignee: ELPIDA MEMORY, INC., Tokyo (JP)

(21) Appl. No.: 12/923,712

(22) Filed: Oct. 5, 2010

(30) Foreign Application Priority Data
Oct. 9, 2009 (JP) 2009-235495

(51) Int. Cl. H01L 23/48

(52) U.S. Cl. 257/773; 257/E23.01

(57) ABSTRACT

A semiconductor device includes a semiconductor chip and a package substrate on which the semiconductor chip is mounted. The package substrate has internal terminals connected to the semiconductor chip, front surface wirings connected to the internal terminals, rear surface wirings connected to external electrodes, and contacts connecting the front surface wiring and rear surface wiring. Out of the plurality of contact, some contacts included in the wirings for signal transmission are disposed near the internal terminals. Thus, a signal led out from the semiconductor chip is immediately taken away from the chip mounting surface of the package substrate. This reduces the floating capacitance between the wirings on the package substrate and chip, thereby improving the signal quality.

### BACKGROUND OF THE INVENTION

1. Field of the Invention

The present invention relates to a semiconductor package substrate and a semiconductor device having the semiconductor package substrate and, more particularly, relates to a semiconductor package substrate having a plurality of wiring layers and a semiconductor device having the same.

2. Description of Related Art

As a semiconductor package substrate such as a BGA substrate, there is known a multilayer substrate as disclosed in Japanese Patent Application Laid Open No. 2008-135772. However, the cost of the semiconductor package substrate increases as the number of wiring layers increases, so that it is preferable to adopt a configuration as disclosed in Japanese Patent Application Laid Open No. 2007-235009 in which the both surfaces of the substrate are used as the wiring layers in order to achieve low cost.

The semiconductor package substrate disclosed in Japanese Patent Application Laid Open No. 2007-235009 has a configuration in which each wiring is led out near a corresponding external terminal (ball electrode) by using a wiring layer on the front surface on which the semiconductor chip is mounted and connected to a wiring layer on the rear surface via a contact electrode. Thus, in the wiring layer on the rear surface, a short wiring for connecting the contact electrode and external terminal will suffice.

In recent years, the number of external terminals, particularly, data I/O terminals is increasing in a semiconductor chip such as a DRAM (Dynamic Random Access Memory), which leads to a difficulty in layout of the wiring on the package in the case of the semiconductor package described in Japanese Patent Application Laid Open No. 2007-235009. In addition, in a general DRAM, a bump electrode on the chip is disposed not in the periphery of the chip but in the center thereof, so that when rewiring is done mainly using the wiring layer on the front surface on which the semiconductor chip is mounted as in the case of the semiconductor package described in Japanese Patent Application Laid Open No. 2007-235009, the floating capacitance between the wirings on the package substrate and chip increases, which may result in a degradation of signal quality.

### SUMMARY

In one embodiment, there is provided a semiconductor device comprising: a semiconductor chip having a plurality of signal terminals arranged in a center portion thereof; and a package substrate on which the semiconductor chip is mounted, wherein the package substrate includes a first wiring layer in which a plurality of first signal lines each connected to an associated one of the signal terminals are provided, a second wiring layer in which a plurality of second signal lines are provided, and a plurality of signal contacts each of which connects an associated one of the first signal lines and an associated one of the second signal lines, and the signal contacts are disposed adjacent to the center portion of the semiconductor chip.

According to the present invention, the signal contacts of the package substrate are disposed adjacent to one another in the portion corresponding to the center of the semiconductor chip, so that a signal led out from the bump of the semiconductor chip is immediately taken away from the chip mounting surface of the package substrate. This reduces the floating capacitance between the wirings on the package substrate and chip, thereby improving the signal quality.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view schematically illustrating a structure of a semiconductor device 10 according to a preferred embodiment of the present invention;

FIGS. 2A to 2C are schematic views illustrating some patterns of the wiring 50;

FIG. 3A is a plan view transparently illustrating the package substrate P;

FIG. 3B is a cross-sectional view taken along the B-B line of FIG. 3A;

FIG. 4 is a plan view illustrating a concrete layout of the first surface Pa of the package substrate P;

FIG. 5 is a plan view illustrating a concrete layout of the second surface Pb of the package substrate P;

FIG. 6 is a diagram for explaining a configuration to balance loads of two wirings that simultaneously transmit signals; and

FIG. 7 is a cross-sectional view schematically illustrating a structure of a semiconductor device 10a according to a modification of the present invention.

### DETAILED DESCRIPTION OF THE PREFERRED EMBODIMENTS

Preferred embodiments of the present invention will be explained below in detail with reference to the accompanying drawings.

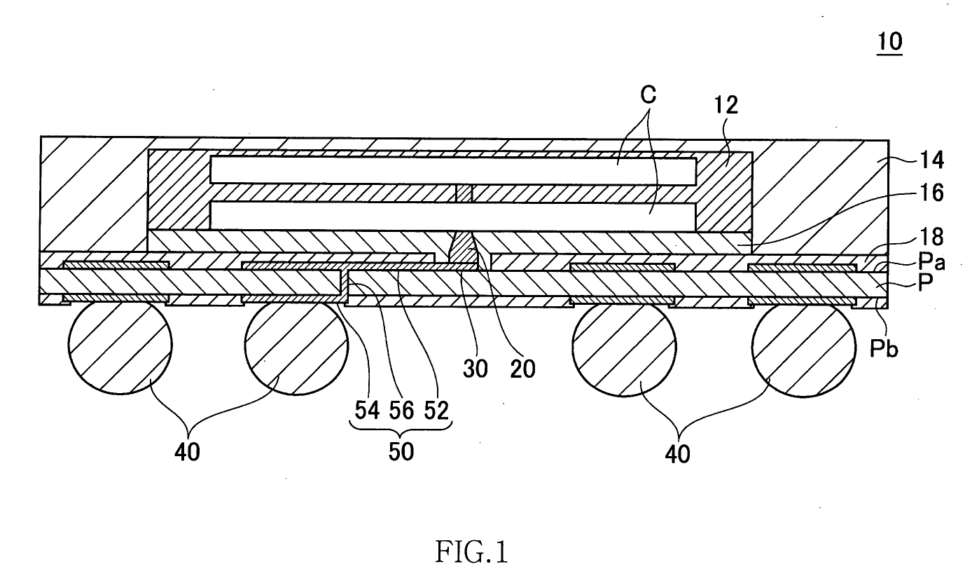

FIG. 1 is a cross-sectional view schematically illustrating a structure of a semiconductor device 10 according to a preferred embodiment of the present invention.

As shown in FIG. 1, the semiconductor device 10 of the present embodiment includes two semiconductor chips C and a package substrate P on which the semiconductor chips C are mounted. Although a plurality of semiconductor chips C are stacked on the package substrate P in the example of FIG. 1, the number of the semiconductor chips C to be mounted is not especially limited in the present invention. As one example, a DDR 3 type DRAM is used as the semiconductor chip C in the present embodiment. Although not especially limited, the thickness of the semiconductor chip C is reduced to about 40 μm. The periphery of the semiconductor chip C is covered by an underfill material 12, and the surface thereof is covered by a resin 14.

The semiconductor chip C is mounted, through a paste material 16, on one (first) surface Pa side of the package substrate P on which a solder resist 18 is provided. Further, on the first surface Pa of the package substrate P, internal terminals 30 being flip-chip connected to bumps 20 of the semiconductor chip C are provided. On the other (second) surface Pb of the package substrate P, external terminals 40 are provided. Further, a plurality of wirings 50 for electrically connecting the plurality of internal terminals 30 and their corresponding plurality of external terminals 40 are formed in the package substrate P. The details of the wirings 50 will be described later.

In the present embodiment, the bumps 20 are arranged in the center portion of the semiconductor chip C. Since FIG. 1 illustrates the cross-section perpendicular to the arrangement direction of the bumps 20, only one bump 20 and one internal terminal 30 are illustrated.

As described above, the wiring 50 formed in the package substrate P electrically connects the internal terminal 30 and its corresponding external terminal 40. Thus, each wiring 50 includes a front surface wiring 52 formed on the first surface Pa, a rear surface wiring 54 formed on the second surface Pb, and a contact 56 for short-circuiting the wirings 52 and 54. The front surface wiring 52 and rear surface wiring 54 are formed so as to extend in parallel to the main surfaces (Pa and Pb) of the package substrate P, and contact 56 is formed so as to penetrate the package substrate P.

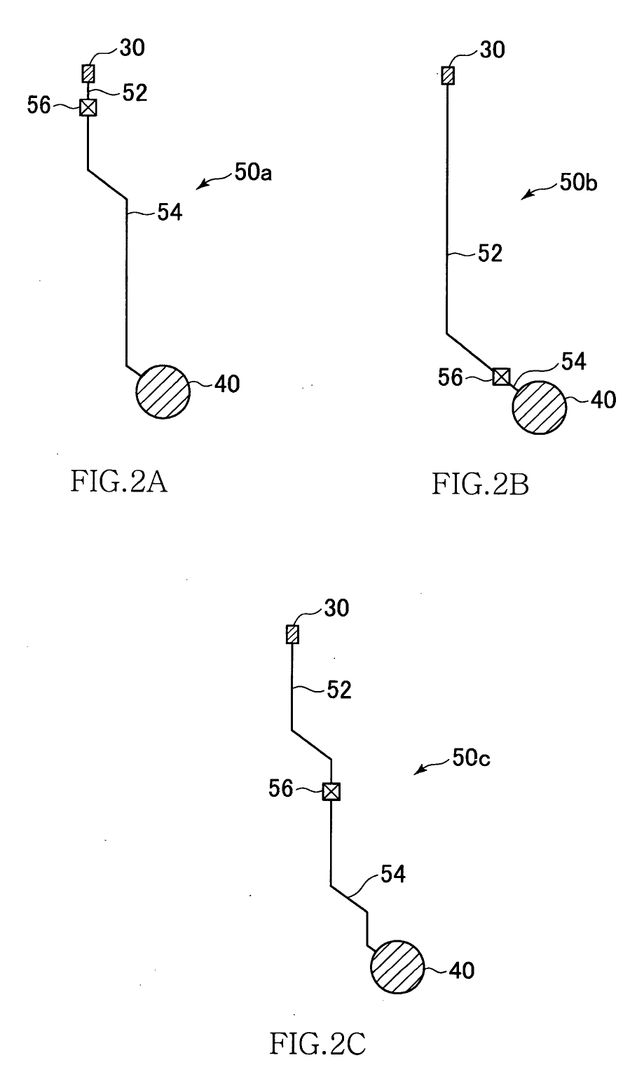

FIGS. 2A to 2C are schematic views illustrating some patterns of the wiring 50.

A pattern of FIG. 2A illustrates an example in which the contact 56 is disposed adjacent to the internal terminal 30. In this case, the front surface wiring 52 is extremely short and, conversely, the rear surface wiring 54 is long. In the present embodiment, the wiring 50a of this pattern is used mainly for a signal wiring. The signal wiring is a wiring for transmitting an address signal for specifying a memory cell to be accessed, a command signal (/RAS, /CAS, /WE, clock enable signal, ODT signal, etc.) for specifying various functional operations, a chip select signal, a data input/output signal, a data system signal (data mask signal, DQS signal) for controlling the data input/output signal, and the like. When the pattern of FIG. 2A is used for the signal wiring, the length of the front surface wiring 52 located near the chip is extremely reduced to reduce the parasitic capacitance between the chip and wiring with the result that the signal quality can be improved.

A pattern of FIG. 2B illustrates an example in which the contact 56 is disposed adjacent to the external terminal 40. In this case, the rear surface wiring 54 is extremely short and, conversely, the front surface wiring 52 is long. In the present embodiment, the wiring 50b of this pattern is used mainly for a power supply wiring. The power supply wiring includes not only a wiring for supplying an operation power but also a wiring for supplying a reference potential. In the wiring 50b of this pattern, the occupied area of the rear surface wiring 54 is extremely small, so that it is possible to reduce the wiring density on the second surface Pb of the package substrate P. That is, when the pattern of the wiring 50a illustrated in FIG. 2A is applied to all the wirings, the wiring density on the second surface Pb becomes excessively high, which may disable installation of the wiring in some cases. Thus, when the pattern of the wiring 50b illustrated in FIG. 2B is applied to some of the wirings, i.e., some of the power supply wirings, the wiring density on the second surface Pb is reduced to increase the flexibility of the layout, allowing the pattern of the wiring 50a illustrated in FIG. 2A to be applied to all the signal wirings.

FIG. 2C illustrates a wiring 50C of a pattern not belonging to any one of the above patterns of FIGS. 2A and 2B. This wiring 50C may be used for the power supply wiring as needed.

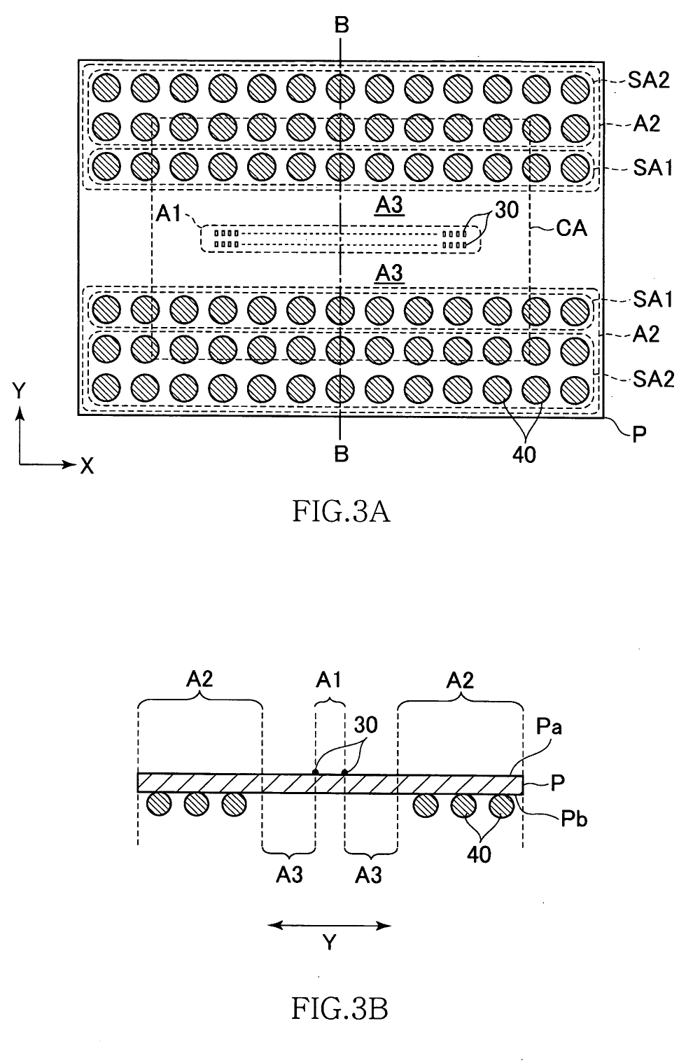

FIG. 3A is a plan view transparently illustrating the package substrate P, and FIG. 3B is a cross-sectional view taken along the B-B line of FIG. 3A.

As illustrated in FIG. 3A, the internal terminals 30 are arranged in area A1 extending in the X-direction in the center portion of the package substrate P. A symbol CA in FIG. 3A is an area on which the semiconductor chip C is mounted. In the present embodiment, the semiconductor chip C is subjected to flip-chip connection; naturally, the area A1 is covered by the mounting area CA of the semiconductor chip C. Further, an area A3 to be described later is also covered by the mounting area CA of the semiconductor chip C except for X-direction both end portions.

The external terminals 40 are arranged in areas A2 located on Y-direction both sides of the package substrate P. Although not apparent in the transparent view of FIG. 3A, the area A1 is disposed on the first surface Pa of the package substrate P, and areas A2 are disposed on the second surface Pb of the package substrate P, as illustrated in FIG. 3B. In the planar view, i.e., as viewed in the direction perpendicular to the main surfaces (Pa and Pb), the area A1 and areas A2 are disposed at positions that do not overlap each other.

An area sandwiched between the area A1 and areas A2 in the planar view is an area A3. In the area A3, the contacts 56 of many (not all) wirings are provided.

A more detailed description will be given below. The external terminals 40 are arranged in a plurality of rows in the X-direction as illustrated in FIG. 3A. Each of the areas A2 in which the external terminals 40 are provided includes a sub area SA1 in which one row of the external terminals 40 nearest to the area A1 is disposed and a sub area SA2 in which other rows of the external terminals 40 are disposed.

The external terminals 40 disposed in the sub area SA1 are connected to their corresponding internal terminals 30 through the wiring 50a or wiring 50b of the pattern illustrated in FIG. 2A or FIG. 2B. The contacts 56 of the wirings are not disposed in the areas A2 but are all disposed in the area A3. In the present embodiment, out of the external terminals 40 disposed in the sub area SA1, some external terminals 40 assigned to the signal (address, data, etc.) are connected to their corresponding internal terminals 30 all through the wirings 50a of the pattern illustrated in FIG. 2A and others assigned to the power supply are connected to their corresponding terminals 30 through the wiring 50a or wiring 50b of the pattern illustrated in FIG. 2A or FIG. 2B.

The external terminals 40 disposed in the sub area SA2 are connected to their corresponding internal terminals 30 through any one of the wirings 50a to 50c of the patterns illustrated in FIGS. 2A to 2C. In the present embodiment, out of the external terminals 40 disposed in the sub area SA2, some external terminals 40 assigned to the signal (address, data, etc.) are connected to their corresponding internal terminals 30 all through the wirings 50a of the pattern illustrated in FIG. 2A, and the contacts 56 of the wirings 50a are not disposed in the areas A2 but are disposed in the area A3. The other external terminals 40 assigned to the power supply are connected to their corresponding internal terminals 30 through any one of the wirings 50a to 50c of the patterns illustrated in FIGS. 2A to 2C. In this case, the contacts 56 are disposed in the area A3 in the case of the wiring 50a or wiring 50b and disposed in the area A2 in the case of the wiring 50b.

As described above, in the present embodiment, the external terminals 40 assigned to the signal are connected to their corresponding internal terminals 30 all through the wirings 50a of the pattern illustrated in FIG. 2A regardless of the position in the area A2, the floating capacitance between the wirings and chip is reduced even though the entire surface of the front surface wiring 52 assigned to the signal is covered by the semiconductor chip C, thereby improving the signal quality. Meanwhile, anyone of the wirings 50a to 50c may appropriately be used for the external terminals 40 assigned to the power supply, so that it is possible to reduce the wiring density of the rear surface wirings 54 as needed.

The present embodiment will further be described with reference to a more specific layout.

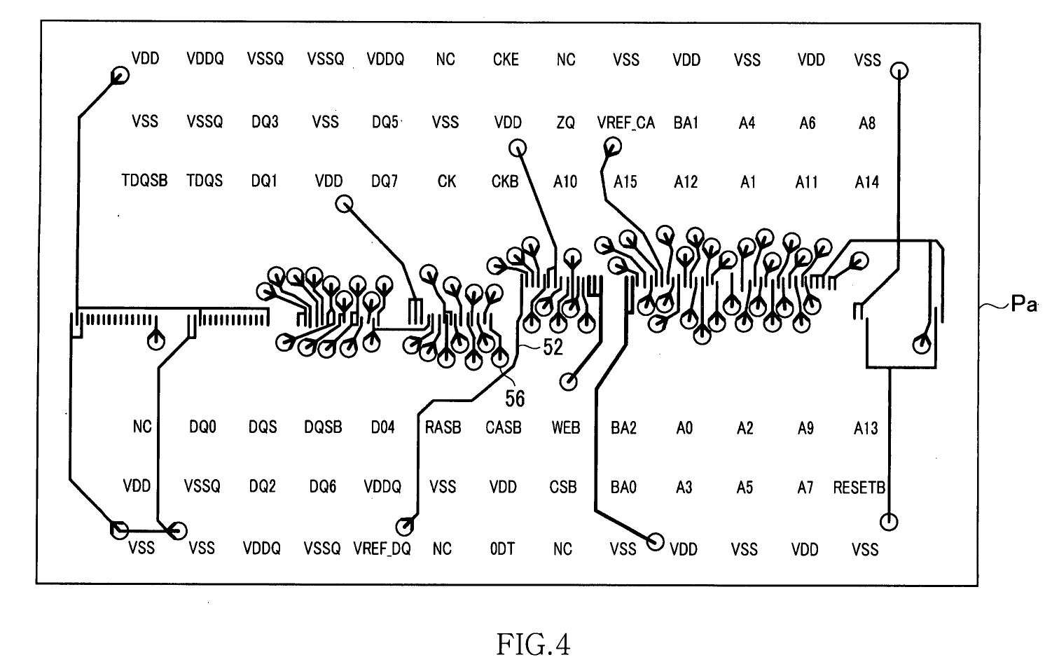

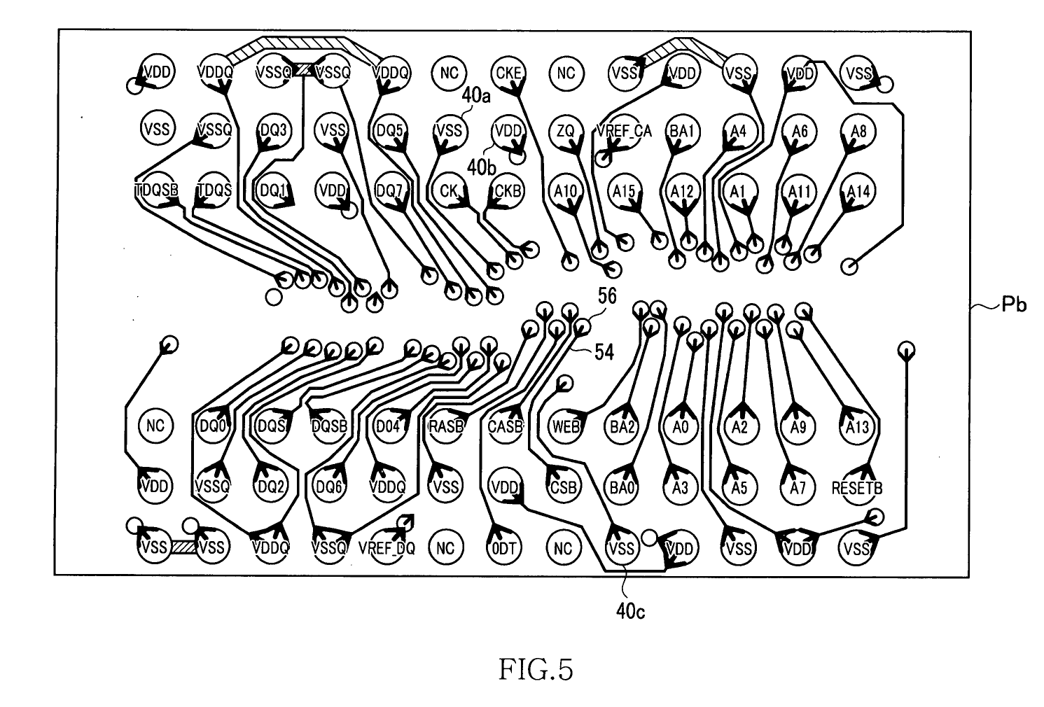

FIG. 4 is a plan view illustrating a concrete layout of the first surface Pa of the package substrate P, and FIG. 5 is a plan view illustrating a concrete layout of the second surface Pb of the package substrate P.

In the examples of FIGS. 4 and 5, the wirings 50a of the pattern illustrated in FIG. 2A are used for all address signals (A0 to A15, BA0 to BA3), all command signals (RASB, CASB, WEB, CSB, ODT, CKE), all clock signals (CK, CKB), and all data signals (DQ0 to DQ7, DM, DQS, DQSB). That is, the contacts 56 of these wirings 50a are disposed adjacent to one another in the portion corresponding to the center of the semiconductor chip C. For example, although the external terminals DQ2, DQ3, DQ5, and DQ6 are disposed in the sub area SA2, the wirings 50a of the pattern illustrated in FIG. 2A are used, and the contacts 56 thereof are disposed nearer to the area A1 than to the area A2.

On the other hand, any one of the wirings 50a to 50c of the patterns illustrated in FIGS. 2A to 2C is used for the power supply (VDD, VSS, VDDQ, VSSQ) and reference voltage VREF. For example, the external terminal 40a (VCC terminal) illustrated in FIG. 5 is connected to the internal terminal 30 through the wiring 50a of the pattern illustrated in FIG. 2A, and the contacts 56 of the wiring 50a is disposed in the area A3. The external terminal 40b (VDD terminal) is connected to the internal terminal 30 through the wiring 50b of the pattern illustrated in FIG. 2B, and the contacts 56 of the wiring 50B is disposed in the area A2. The external terminal 40c (VSS terminal) is connected to the internal terminal 30 through the wiring 50c of the pattern illustrated in FIG. 2C, and the contacts 56 of the wiring 50c is disposed nearer to the area A2 than to the area A1.

In the present embodiment, the external terminals 40 assigned to the signal are connected to their corresponding internal terminals 30 all through the wirings 50a of the pattern illustrated in FIG. 2A, so that the floating capacitance between the wirings and chip is reduced as described above. In addition, the external terminals 40 assigned to the power supply are connected to their corresponding internal terminals 30 through any arbitrary one of the wirings 50a to 50c depending on their positions, so that it is possible to reduce the wiring density of the rear surface wirings 54 formed in the area A3.

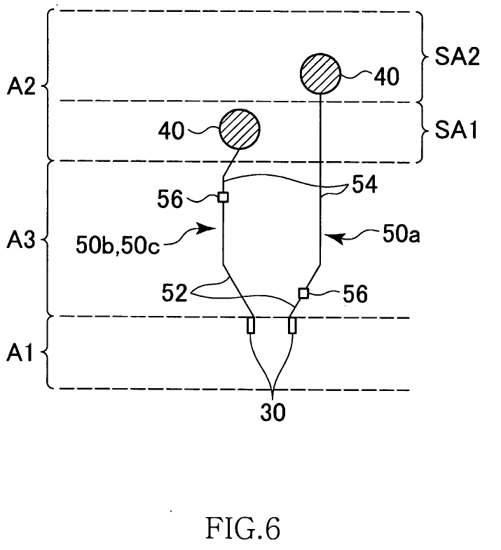

However, in the present invention, it is not essential that the wiring 50a of the pattern illustrated in FIG. 2A be used for all the external terminal 40 assigned to the signal. That is, the wiring 50b or wiring 50c of the pattern illustrated in FIG. 2B or FIG. 2C may be used for some of the external terminals 40 assigned to the signal as long as the contact 56 is disposed in the area A3. In this case, as illustrated in FIG. 6, in consideration of the balance of the floating capacitance given to the wirings, it is preferable that the wiring 50a of the pattern illustrated in FIG. 2A be preferentially used for a wiring 50 having a long (i.e., floating capacitance is large) wiring length and that the wiring 50b or wiring 50c of the pattern illustrated in FIG. 2B or FIG. 2C be used for a wiring 50 having a short (i.e., floating capacitance is small) wiring length 50. The wiring 50 having a long wiring length is a wiring corresponding to the external terminal 40 disposed in, e.g., the sub area SA2, and the contact 56 included in the wiring only need to be disposed within the area A3 at a position nearer to the area A1 than to area A2. The wiring 50 having a short wiring length is a wiring corresponding to the external terminal 40 disposed in, e.g., the sub area SA1, and the contact 56 included in the wiring only need to be disposed within the area A3 at a position nearer to the area A2 than to the area A1. With the above configuration, a difference in the load between the wirings that need to simultaneously transmit signals is reduced, so that the skew between signals is reduced.

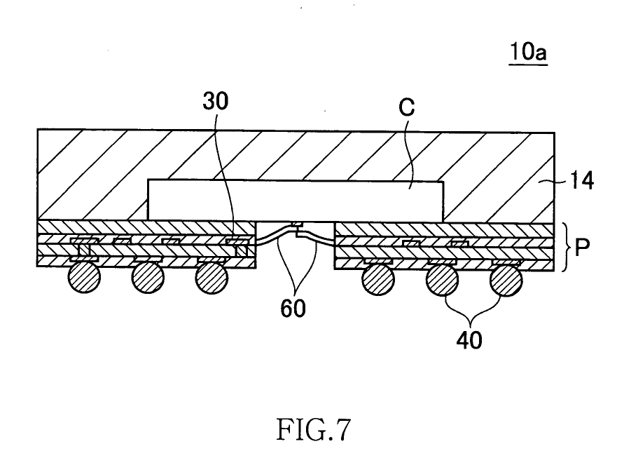

FIG. 7 is a cross-sectional view schematically illustrating a structure of a semiconductor device 10a according to a modification of the present invention.

In the example of FIG. 7, the semiconductor chip C mounted on the package substrate P is connected to the internal terminals 30 through inner leads 60. As described above, a connection between the semiconductor chip C and package substrate P may be achieved by other means than the bump 20.

It is apparent that the present invention is not limited to the above embodiments, but may be modified and changed without departing from the scope and spirit of the invention.

For example, the type of the semiconductor chip C to be used in the present invention is not especially limited to a DRAM, and other semiconductor memory such as an SRAM, a flash memory, an MRAM, a PRAM, an RRAM, or a logic-based semiconductor IC such as a CPU or a DSP may be used.

Further, the number of the wiring layers formed on the package substrate P in the present invention need not be two, but three or more wiring layers may be formed.

What is claimed is:

1. A semiconductor device comprising:
a semiconductor chip having a plurality of signal terminals arranged in a center portion thereof; and
a package substrate on which the semiconductor chip is mounted, wherein
the package substrate includes a first wiring layer in which a plurality of first signal lines each connected to an associated one of the signal terminals are provided, a second wiring layer in which a plurality of second signal lines are provided, and a plurality of signal contacts each of which connects an associated one of the first signal lines and an associated one of the second signal lines, and
the signal contacts are disposed adjacent to the center portion of the semiconductor chip.

2. The semiconductor device as claimed in claim 1, wherein the second signal lines are longer than the first signal lines.

3. The semiconductor device as claimed in claim 1, wherein the first signal lines are entirely covered by the semiconductor chip.

4. The semiconductor device as claimed in claim 1, wherein
the package substrate further includes a plurality of external terminals that are provided on the second wiring layer, and
each of the external terminals is connected to an associated one of the second signal lines.

5. The semiconductor device as claimed in claim 1, wherein
the semiconductor chip further has a power supply terminal,
the first wiring layer has a first power supply line connected to the power supply terminal,
the second wiring layer has a second power supply line connected to the first power supply line through a power supply contact,
the package substrate further includes an external power supply terminal connected to the second power supply line, and
the power supply contact is disposed adjacent to the external power supply terminal.

6. The semiconductor device as claimed in claim 5, wherein the second power supply line is shorter than the first power supply line.

7. A semiconductor package substrate on which a semiconductor chip is to be mounted, comprising:
a first surface having a first area;
a second surface that is opposite to the first surface and has a second area which does not overlap the first area;
a plurality of internal terminals provided in the first area;
a plurality of external terminals provided in the second area; and
a plurality of wirings each of which electrically connects an associated one of the internal terminals and an associated one of the external terminals, wherein
each of the wirings includes a front surface wiring positioned relatively on the first surface side and extended in parallel to the first surface, a rear surface wiring positioned relatively on the second surface side and extended in parallel to the second surface and a contact that connects the front surface wiring and its corresponding rear side wiring,
the wirings include a plurality of signal wirings, and
the contacts included in the signal wirings are not disposed in the second area but disposed in a third area sandwiched between the first and second areas in the planar view.

8. The semiconductor package substrate as claimed in claim 7, wherein
the second area includes a first sub area opposed to the first area through the third area and a second sub area located on the opposite side to the first and third areas with respect to the first sub area,
the plurality of external terminals include a plurality of first external terminals disposed in the first sub area and a plurality of second external terminals disposed in the second sub area, and
the plurality of signal wirings include first wirings connected to the first external terminal and second wirings connected to the second external terminals.

9. The semiconductor package substrate as claimed in claim 8, wherein the contacts included in the second wirings are disposed nearer to the first area than to the second area.

10. The semiconductor package substrate as claimed in claim 8, wherein
the wirings further include a third wiring that supplies a first power supply,
the third wiring is connected to any one of the plurality of second external terminals, and
the contact included in the third wiring is disposed in the second area.

11. The semiconductor package substrate as claimed in claim 8, wherein
the wirings further include a fourth wiring that supplies a second power supply,
the fourth wiring is connected to any one of the plurality of second external terminals, and
the contact included in the fourth wiring is disposed within the third area at a position nearer to the second area than to the first area.

12. The semiconductor package substrate as claimed in claim 7, wherein
out of the plurality of signal wirings, some wirings that need to simultaneously transmit predetermined signals include a fifth wiring having a relatively short wiring length and a sixth wiring having a relatively long wiring length, and
the front surface wiring included in the sixth wiring is shorter than the front surface wiring included in the fifth wiring.

13. The semiconductor package substrate as claimed in claim 12, wherein the rear surface wiring included in the six wiring is longer than the rear surface wiring included in the fifth wiring.

14. A semiconductor device comprising:
a semiconductor package substrate; and
a semiconductor chip mounted on the semiconductor package substrate, wherein
the semiconductor package substrate comprises:
a first surface having a first area;
a second surface that is opposite to the first surface and has a second area which does not overlap the first area;
a plurality of internal terminals provided in the first area;
a plurality of external terminals provided in the second area; and
a plurality of wirings each of which electrically connects an associated one of the internal terminals and an associated one of the external terminals, wherein
each of the wirings includes a front surface wiring positioned relatively on the first surface side and extended in parallel to the first surface, a rear surface wiring positioned relatively on the second surface side and extended in parallel to the second surface and a contact that connects the front surface wiring and its corresponding rear side wiring,
the wirings include a plurality of signal wirings, and
the contacts included in the signal wirings are not disposed in the second area but disposed in a third area sandwiched between the first and second areas in the planar view.

15. The semiconductor device as claimed in claim 14, wherein the third area is covered by the semiconductor chip.
